(19) United States
(12) Patent Application Publication
(10) Pub. No.: US 2009/0236758 A1
(43) Pub. Date: Sep. 24, 2009

(54) SEMICONDUCTOR MODULE

(75) Inventor: Wataru Tsukada, Tokyo (JP)

Correspondence Address: YOUNG & THOMPSON, 209 Madison Street, Suite 500, ALEXANDRIA, VA, 22314, US

(73) Assignee: ELPIDA MEMORY, INC., Tokyo (JP)

(21) Appl. No.: 12/408,981

(22) Filed: Mar. 23, 2009

(30) Foreign Application Priority Data
Mar. 24, 2008 (JP) 2008-075511

(51) Int. Cl. H01L 23/538

(52) U.S. Cl. 257/786; 257/E23.169

(57) ABSTRACT

A semiconductor module has a plurality of semiconductor devices arranged on a substrate and mutually connected by signal bus wiring lines. Each pair of first semiconductor devices are connected to each other by the signal bus wiring lines, skipping a second semiconductor device located between the pair of first semiconductor devices.

This application is based upon and claims the benefit of priority from Japanese patent application No. 2008-75511, filed on Mar. 24, 2008, the disclosure of which is incorporated herein in its entirety by reference.

### BACKGROUND OF THE INVENTION

1. Field of the Invention

The present invention relates to a semiconductor module having a plurality of semiconductor devices arranged on a substrate and mutually connected by signal bus wiring lines.

2. Description of the Related Art

Multi-banked semiconductor device architecture has increased the degree of freedom in arrangement and layout of semiconductor devices. As the degree of freedom in layout is increased by the multi-banking technology, various layout methods have been developed for various purposes, such as for obtaining desirable transmission characteristics and reducing the heat generation.

In recent years, semiconductor devices have been required to operate at a higher speed. It is known, however, that the increase in operating speed is limited partly because the increase in load capacity due to cascade connection or the like of the semiconductor devices causes slew rate distortion, or retards the propagation delay time of an output signal from a sending-end semiconductor device. In addition, as the operation speed is increased, the importance of having a rectangular outline is also increased for semiconductor devices. Thus, some semiconductor device products employ a layout method of arranging semiconductor devices rotated relative to each other.

However, if the rotated semiconductor devices are arranged at small intervals, for example, signal bus wiring lines connecting the rotated semiconductor devices will meander in a narrow wiring region, making it difficult to equalize the wiring lengths. This may induce occurrence of inter-wiring skew or the like and hinder the increase of operating speed.

Further, if unreasonable efforts are made to equalize the wiring lengths, the designer may be forced to employ a layout involving factors opposing the increase of the operating speed, for example a layout in which inter-wiring crosstalk or inter-layer crosstalk is apt to occur, or a layout which hinders the reduction of impedance of power supply to a power supply pin of the semiconductor device.

Techniques relating to such layout methods are described, for example, in Japanese Laid-Open Patent Publication No. 2000-194594 (Patent Document 1), No. 2000-294652 (Patent Document 2), No. 2004-187312 (Patent Document 3), No. 2006-173409 (Patent Document 4), and No. H10-242412 (Patent Document 5).

Patent Documents 1 and 3 disclose techniques in which every second device are connected with a single wiring line which is turned around at the terminal end. Patent Document 2 discloses a technique in which wiring lines are driven at each node. Patent Document 4 discloses a common module wiring technique. Patent Document 5 discloses a common wiring technique to equalize the wiring lengths.

### SUMMARY

The present invention seeks to solve one or more of the above problems, or to improve upon those problems at least in part.

In one embodiment, a semiconductor module has a plurality of semiconductor devices arranged on a substrate and mutually connected by means of signal bus wiring lines. Each pair of first semiconductor devices are connected to each other by the signal bus wiring lines, skipping a second semiconductor device located between the pair of first semiconductor devices.

### BRIEF DESCRIPTION OF THE DRAWING

The above features and advantages of the present invention will be more apparent from the following description of certain preferred embodiments taken in conjunction with the accompanying drawings, in which

FIG. 1 is a diagram for explaining a first related art;

FIG. 2 is a diagram for explaining a second related art;

FIG. 3 is a diagram for explaining a first embodiment of the present invention;

FIG. 4 is a diagram for explaining a second embodiment of the present invention;

FIG. 5 is a diagram for explaining a third embodiment of the present invention;

FIG. 6 is a diagram for explaining a fourth embodiment of the present invention;

FIG. 7 is a diagram for explaining a fifth embodiment of the present invention;

FIG. 8 is a diagram for explaining a sixth embodiment of the present invention;

FIG. 9 is a diagram for explaining a seventh embodiment of the present invention;

FIG. 10 is a diagram showing that signal bus wiring lines are driven by two sending-end semiconductors, respectively; and

FIG. 11 is a diagram showing that signal bus wiring lines are driven by a single sending-end semiconductor.

### DETAILED DESCRIPTION OF EXEMPLARY EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

In the first place related arts will be described to clarify the features of the present invention.

### (First Related Art)

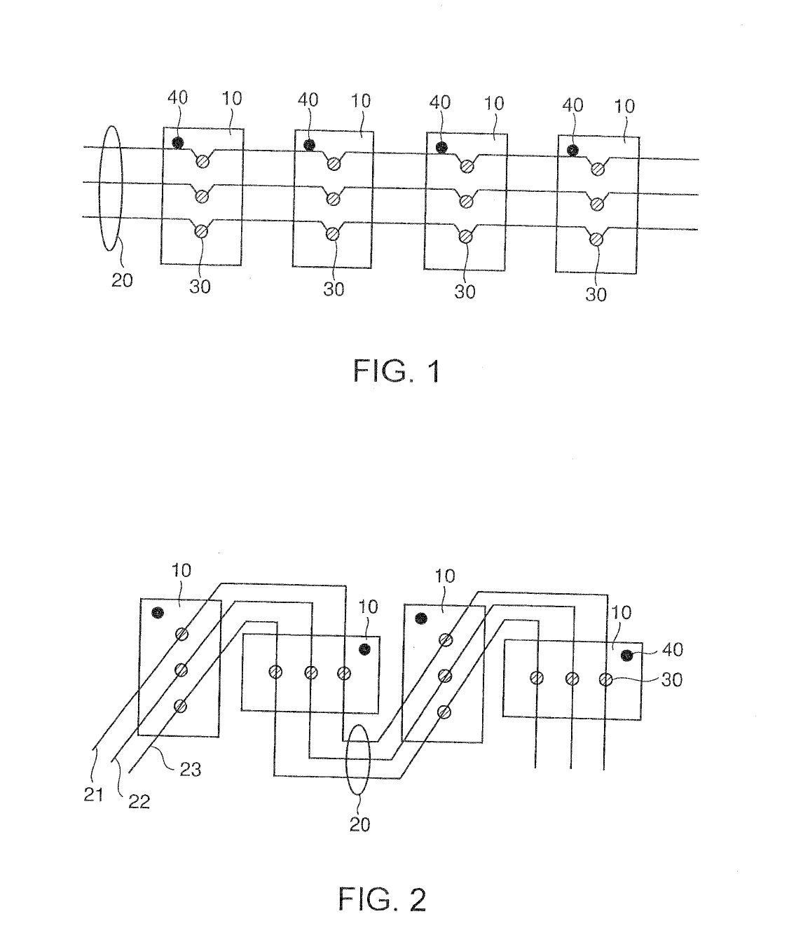

Referring to FIG. 1, a first related art will be described.

A plurality of semiconductor devices 10 are connected to signal bus wiring lines 20 the lengths of which are to be equalized. Each semiconductor device 10 is provided with via holes 30 and an index 40. The signal bus wiring lines 20 are connected to the semiconductor devices 10 through the via holes 30.

In the first related art, the signal bus wiring lines 20 distributes a signal to be transmitted either leftward or rightward as viewed in the figure, to the semiconductor devices 10 in sequence. If n semiconductor devices 10 are connected to the signal bus wiring lines 20, the number of loads is also n. In the recent trend of the increase in operating speed of the semiconductor devices 10, there have arisen demands for a layout elaborated to cope with the increased operating speed, since a layout simply cascade-connecting the semiconductor devices 10 will face problems such as slew rate distortion caused by the load capacity of the semiconductor devices 10 and increase of output signal propagation delay time from the sending-end semiconductor device.

### (Second Related Art)

Next, a second related art will be described with reference to FIG. 2.

Description will be made, as an example, in terms of a case in which semiconductor devices 10 are rotated by 90 degrees. A plurality of semiconductor devices 10 are connected to signal bus wiring lines 20 the lengths of which are to be equalized. Each semiconductor device 10 is provided with via holes 30 and an index 40. The signal bus wiring lines 20 are connected to the semiconductor devices 10 through the via holes 30.

The signal bus wiring lines 20 are laid in a meandering manner to connect the via holes 30 which connect the semiconductor devices 10 and the signal bus wiring lines 20. Specifically, the signal bus wiring lines 21, 22, and 23 are repeatedly turned inward and outward according to the orientations of the semiconductor devices 10.

In general, a set of signal bus wiring lines 20 consists of several tens of lines. An approximately same number of via holes 30 are formed on the periphery of each semiconductor device 10. Although the lengths of the signal bus wiring lines 20 connecting the semiconductor devices 10 need be equalized, the wiring region is small when the semiconductor devices 10 are arranged at small intervals. Therefore, the equalization of length is achieved by employing a meandering wiring method or the like while arranging adjacent wiring lines at a narrow pitch.

The wiring lines arranged at a narrow pitch are susceptible to crosstalk. Further, the wiring lines arranged at a narrow pitch are difficult to take measures to avoid inter-layer crosstalk, for example to dislocate the wiring lines. Still further, in some cases, the via holes connecting the semiconductor devices 10 to a power supply pin in a minimum distance are obliged to be omitted in order to pass the signal bus wiring lines 20, which will presumably increase the resistance of power supply to the semiconductor devices 10.

Next, preferred exemplary embodiments of the present invention will be described with reference to the drawings.

### First Exemplary Embodiment

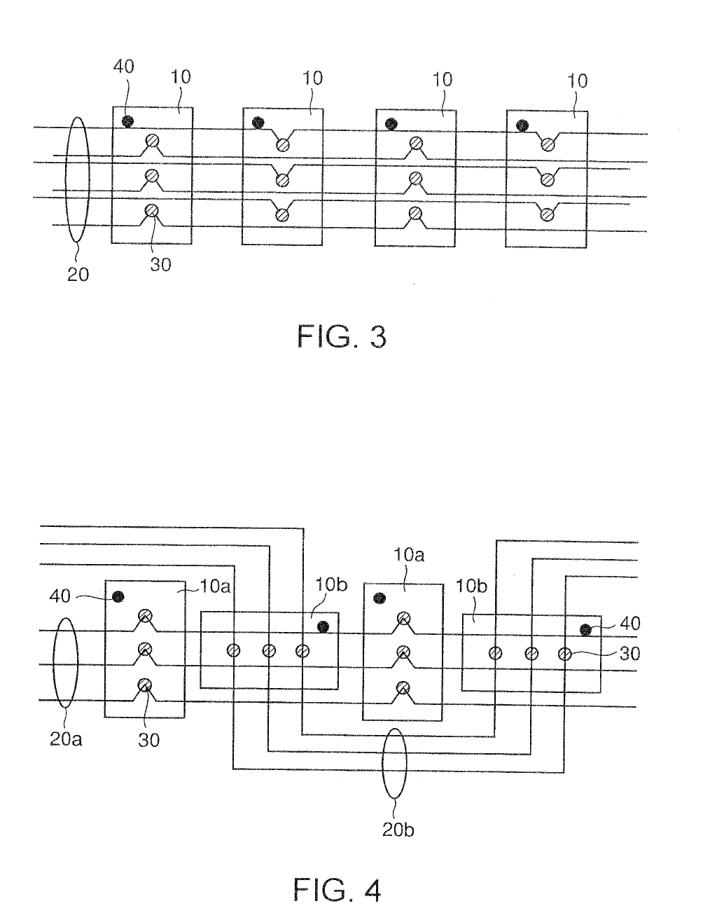

Referring to FIG. 3, a first exemplary embodiment of the present invention will be described.

The first exemplary embodiment relates to a semiconductor module having a plurality of semiconductor devices arranged on a substrate and mutually connected by means of signal bus wiring lines.

As shown in FIG. 3, the plurality of semiconductor devices 10 are connected to signal bus wiring lines 20 the lengths of which are to be equalized. Each semiconductor device 10 is provided with via holes 30 and an index 40. The signal bus wiring lines 20 are connected to the semiconductor devices 10 through the via holes 30.

The semiconductor devices 10 are connected through the via holes 30, skipping one semiconductor 10 each time. The number of semiconductor devices 10 to skip is not limited to one, but two, three, or n semiconductor devices may be skipped.

According to the first exemplary embodiment, comparing with the first related art shown in FIG. 1, the number of loads placed on the signal bus wiring lines 20 is reduced. This increases the amount of current, and causes the slew rate to rise steeply. Thus, improvement of waveform distortion can be expected. At the same time, since the load is reduced, the propagation delay time from the transmission end can be reduced.

### Second Exemplary Embodiment

Referring to FIG. 4, a second exemplary embodiment of the present invention will be described.

The second exemplary embodiment relates to a semiconductor module having a plurality of semiconductor devices arranged on a substrate and mutually connected by means of signal bus wiring lines.

Description will be made, as an example, in terms of a case in which the semiconductor devices are rotated by 90 degrees, as shown in FIG. 4.

A plurality of semiconductor devices 10a are connected to signal bus wiring lines 20a the lengths of which are to be equalized. On the other hand, a plurality of semiconductor devices 10b are connected to bus wiring lines 20b the lengths of which are to be equalized. Each semiconductor device 10a, 10b is provided with via holes 30 and an index 40. The signal bus wiring lines 20a and 20b are connected to the semiconductor devices 10a and 10b through the via holes 30, respectively.

With this structure, the semiconductor devices 10a and 10b are connected, skipping those semiconductor devices rotated to be oriented to a different direction. Thus, the vertically oriented semiconductor devices 10a are connected by the signal bus wiring lines running only in a horizontal direction. This facilitates the equalization of the wiring line lengths, which was difficult according to the second related art shown in FIG. 2.

In contrast, the signal bus wiring lines connecting the horizontally oriented semiconductor devices 10b are laid in a meandering manner. However, since the semiconductor devices 10b are mutually connected while skipping one semiconductor device 10a having a different angle of rotation, the signal bus wiring lines connecting these semiconductor devices 10b are allowed to have a wiring region sufficient to accommodate the wiring lines turned outward and inward. This facilitates the equalization of the wiring line lengths, and eliminates the need of arranging signal wiring lines at a narrow pitch as is done in the second related art. As a result, the inter-wiring crosstalk and the inter-layer crosstalk can be reduced.

Further, unlike the second related art, the second embodiment eliminates the necessity of omitting power supply via holes for the purpose of equalization of wiring line lengths, and hence power can be supplied to power supply pins of the semiconductor devices 10a and 10b at a low impedance.

### Third Exemplary Embodiment

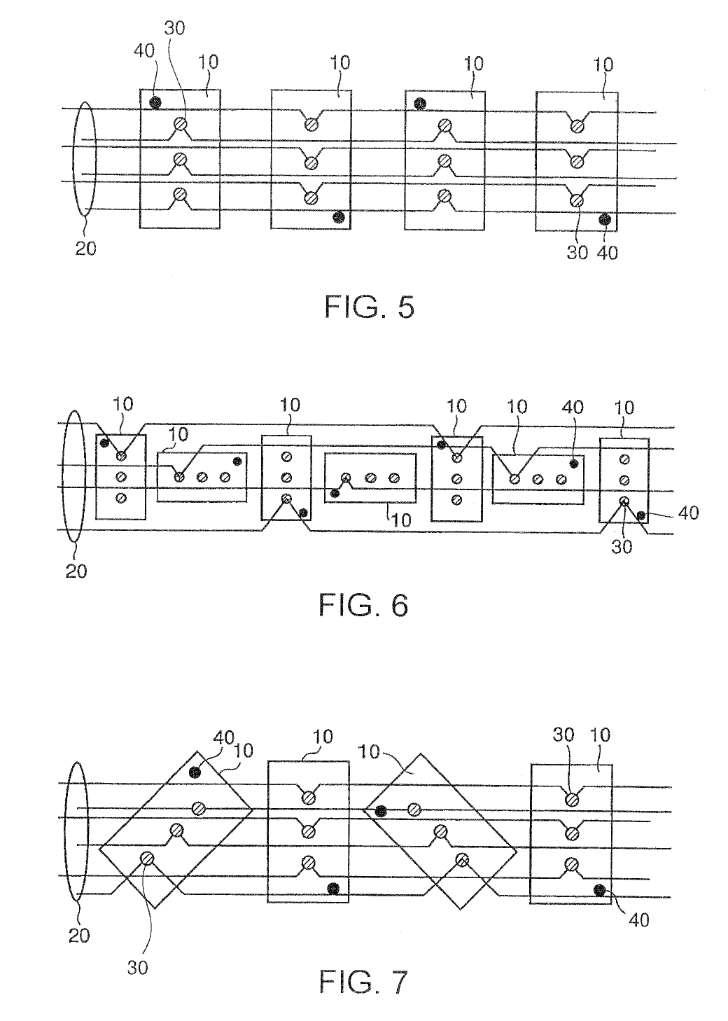

Referring to FIG. 5, a third exemplary embodiment of the present invention will be described.

The third exemplary embodiment relates to a semiconductor module having a plurality of semiconductor devices arranged on a substrate and mutually connected by means of signal bus wiring lines.

As shown in FIG. 5, a plurality of semiconductor devices 10 are connected to signal bus wiring lines 20 the lengths of which are to be equalized. Each semiconductor device 10 is provided with via holes 30 and an index 40. The signal bus wiring lines 20 are connected to the semiconductor devices 10 through the via holes 30.

In the third exemplary embodiment, every second semiconductor device 10 is rotated by 180 degrees, and the semiconductor device 10 are connected through the via holes 30, skipping one semiconductor device 10 each time. The number of semiconductor devices 10 to skip is not limited to one. The semiconductor devices 10 may be connected by skipping two, three, or n semiconductor devices. Further, the angle of rotation need not be exactly the same for all the rotated semiconductor devices, but may be different.

### Fourth Exemplary Embodiment

Referring to FIG. 6, a fourth exemplary embodiment of the present invention will be described.

The fourth exemplary embodiment relates to a semiconductor module having a plurality of semiconductor device arranged on a substrate and mutually connected through signal bus wiring lines.

As shown in FIG. 6, a plurality of semiconductor devices 10 are connected to signal bus wiring lines 20 the lengths of which are to be equalized. Each semiconductor device 10 is provided with via holes 30 and an index 40. The signal bus wiring lines 20 are connected to the semiconductor devices 10 through the via holes 30.

In the fourth exemplary embodiment, as an example, each semiconductor device 10 is rotated by 90 degrees relative to a preceding adjacent one, so that the angle of rotation of the semiconductor devices becomes the same at every fourth semiconductor device. Each signal bus wiring line 20 connects the semiconductor devices 10 having the same angle of rotation.

In the fourth exemplary embodiment, the semiconductor devices 10 assume the same angle of rotation at every fourth semiconductor device. However, the semiconductor devices 10 may be arranged such that the angle of rotation becomes the same at every n-th semiconductor device. Further, the angle of each rotation need not be exactly the same, but may be different.

### Fifth Exemplary Embodiment

Referring to FIG. 7, a fifth exemplary embodiment of the present invention will be described.

The fifth exemplary embodiment relates to a semiconductor module having a plurality of semiconductor devices arranged on a substrate and mutually connected by means of signal bus wiring lines.

As shown in FIG. 7, a plurality of semiconductor devices 10 are connected to signal bus wiring lines 20 the lengths of which are to be equalized. Each semiconductor device 10 is provided with via holes 30 and an index 40. The signal bus wiring lines 20 are connected to the semiconductor devices 10 through the via holes 30.

In the fifth exemplary embodiment, a case is shown, as an example, in which each pair of semiconductor devices 10 are connected by skipping one semiconductor device 10 located therebetween while being rotated by 45 degrees towards the skipped semiconductor device 10 so as to be line symmetric with respect to the skipped one.

Here, the number of semiconductor devices 10 to skip is not limited to one, but the semiconductor devices 10 may be connected, skipping two, three, or n semiconductor devices 10. Further, the angle of rotation of the semiconductor devices 10 which are connected to the same signal bus wiring lines 20, skipping one or more semiconductor devices 10, need not be the same but may be different.

### Sixth Exemplary Embodiment

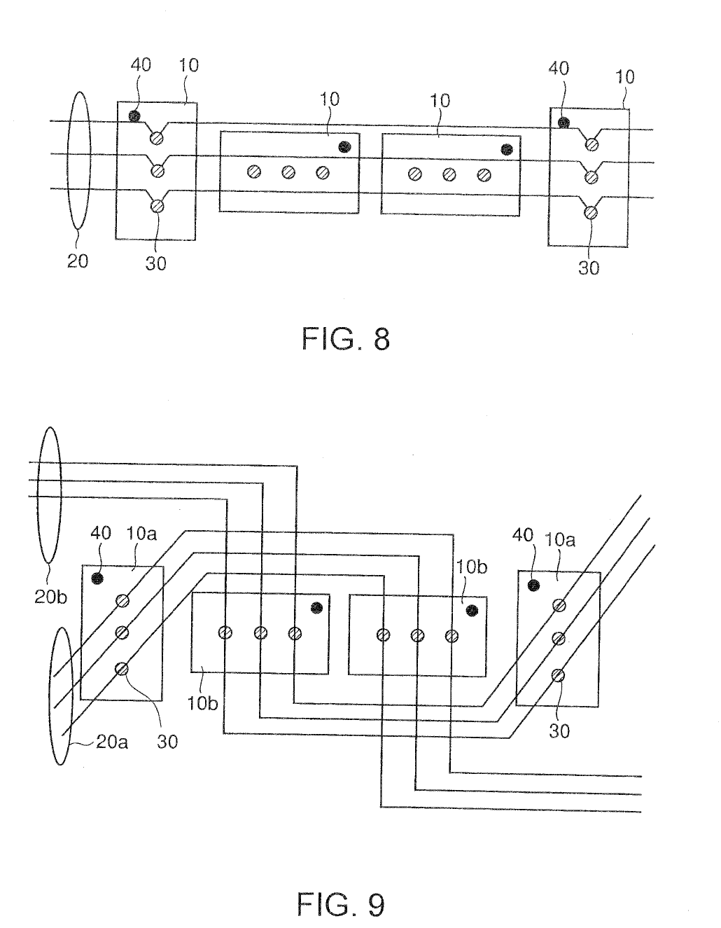

Referring to FIG. 8, a sixth exemplary embodiment of the present invention will be described.

The sixth exemplary embodiment relates to a semiconductor module having a plurality of semiconductor devices arranged on a substrate and mutually connected by means of signal bus wiring lines.

As shown in FIG. 8, a plurality of semiconductor devices 10 are connected to signal bus wiring lines 20 the lengths of which are to be equalized. Each semiconductor device 10 is provided with via holes 30 and an index 40. The signal bus wiring lines 20 are connected to the semiconductor devices 10 through the via holes 30.

The signal bus wiring lines 20 connect each pair of semiconductor device 10 by skipping two semiconductor devices 10 located therebetween.

In the sixth embodiment, the skipped semiconductor devices 10 are rotated by 90 degrees, while the angle of rotation of the connected semiconductor devices 10 is not limited particularly.

### Seventh Exemplary Embodiment

Referring to FIG. 9, a seventh exemplary embodiment of the present invention will be described.

The seventh exemplary embodiment relates to a semiconductor module having a plurality of semiconductor devices arranged on a substrate and mutually connected by means of signal bus wiring lines.

Description will be made of an example in which semiconductor devices are rotated by 90 degrees, as shown in FIG. 9.

Signal bus wiring lines 20a the lengths of which are to be equalized are connected to two semiconductor devices 10a and 10b having different angles of rotation from each other. On the other hand, signal bus wiring lines 20b the lengths of which are to be equalized are also connected to two semiconductor devices 10b and 10a having different angles of rotation from each other. Each of the semiconductor devices 10a, 10b is provided with via holes 30 and an index 40. The signal bus wiring lines 20a and 20b are connected to the semiconductor devices 10a and 10b, respectively, through the via holes 30. Thus, the signal bus wiring lines 20a and 20b connect the semiconductor devices 10a and 10b having different angles of rotation, respectively.

According to the seventh exemplary embodiment, the lengths of the signal bus wiring lines can be equalized easily by being provided with a sufficient wiring region to accommodate the wiring lines turned outward and inward, in the same manner as described in the second embodiment shown in FIG. 4. Further, it is made possible to avoid the arrangement of signal wiring lines at a narrow pitch as is done according to the second related art. Further, the inter-wiring crosstalk and inter-layer crosstalk can be reduced. Still further, unlike the related art, there is no need to omit the power supply via holes for the purpose of equalization of wiring line lengths, and hence power can be supplied to power supply pins of the semiconductor devices at a low impedance.

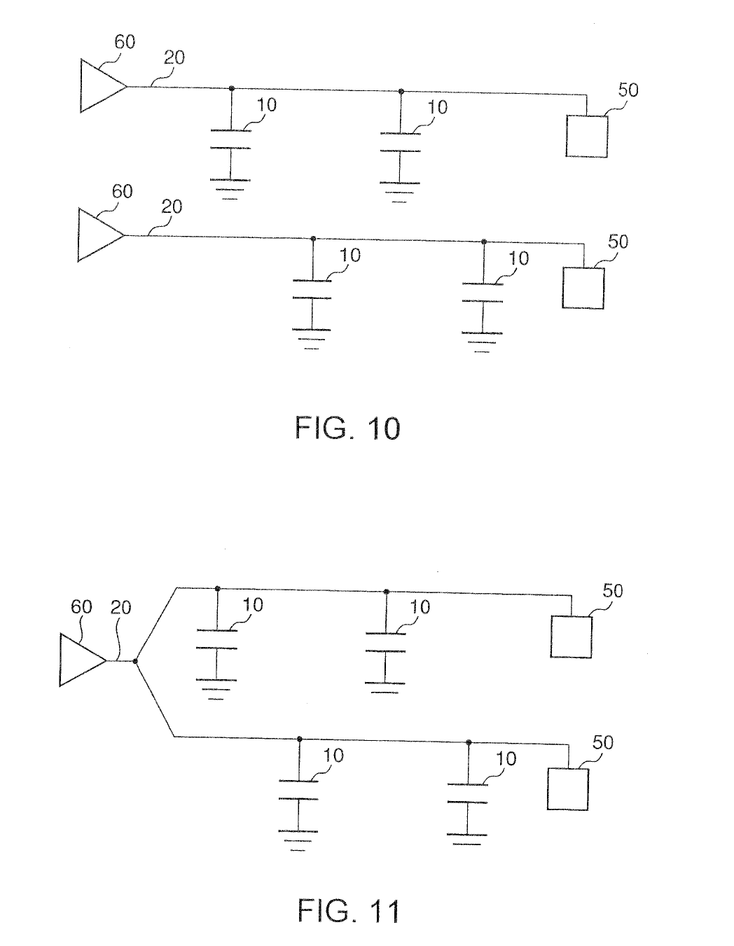

The semiconductor devices 10 according to the first to seventh exemplary embodiments have signal bus wiring lines 20 which are led out from sending-end semiconductor(s) 60 as shown in FIGS. 10 and 11. The semiconductor devices 10 represented as capacitive loads are connected to the signal bus wiring lines 20 to be supplied with power or a signal. The signal bus wiring lines 20 are terminated with terminal elements 50.

FIG. 10 illustrates a configuration in which the signal bus wiring lines 20 are driven by two sending-end semiconductors 60, respectively. FIG. 11 illustrates a configuration in which the signal bus wiring lines 20 are driven by a single sending-end semiconductor 60. The configuration shown in FIG. 11 in which the signal bus wiring lines 20 are connected in parallel has an advantage that the actual load is reduced to about a half.

In the exemplary embodiments of the present invention as described above, the semiconductor devices are mutually connected by skipping one or more semiconductor device(s) located therebetween. The number of semiconductor devices to skip is not limited particularly. The semiconductor devices to be skipped may be rotated to any orientation. When skipping the semiconductor devices oriented to the same direction, the operating speed can be increased due to the reduction of load capacity to the signal bus wiring lines.

When the semiconductor devices are connected by skipping one or more semiconductor devices located therebetween, the load capacity per signal wiring line is reduced and hence improvement of waveform distortion can be expected. Thus, the increase of the operating speed can be achieved.

When the semiconductor devices are connected by skipping one or more semiconductor devices having a different angle of rotation, the wiring region for the signal bus wiring lines is expanded, which makes it easy to equalize the lengths of the signal bus wiring lines. Thus, a layout can be achieved which is able to improve the quality of signals.

The exemplary embodiments of the present invention described above provide advantageous effects as follows.

The first effect is that the load on each signal bus wiring line is reduced by connecting semiconductor devices while skipping one or more semiconductor devices located therebetween. In other words, the reduction of the wiring load is achieved by reducing the number of semiconductor devices connected to each signal bus wiring line. This increases the amount of current and causes the slew rate to rise steeply, improving the waveform distortion. Further, the reduction of the load makes it possible to reduce the propagation delay time from the sending-end semiconductor.

The second effect is that the lengths of the signal bus wiring lines can be equalized easily by connecting semiconductor devices while skipping one or more semiconductor devices arranged by being rotated by a different angle of rotation, especially when the connected semiconductor devices are rotated by the same angle of rotation. Since the lengths of the signal bus wiring lines can be equalized easily, the inter-wiring crosstalk and inter-layer crosstalk can be reduced, and power can be supplied to the power supply pins of the semiconductor devices at low impedance.

Although the present invention has been described in conjunction with a few preferred embodiments thereof, the invention is not limited to the foregoing embodiments but may be modified in various other manners without departing from the scope of the appended claims.

What is claimed is:

1. A semiconductor module having a plurality of semiconductor devices arranged on a substrate and mutually connected by signal bus wiring lines, wherein each pair of first semiconductor devices are connected to each other by the signal bus wiring lines, skipping a second semiconductor device located between the pair of first semiconductor devices.

2. The semiconductor module as claimed in claim 1, wherein the semiconductor devices are cascade-connected by the signal bus wiring lines.

3. The semiconductor module as claimed in claim 1, wherein the number of the second semiconductor devices is N (N is an integer of one or more).

4. The semiconductor module as claimed in claim 1, wherein each of the semiconductor devices comprises a via hole, and
the signal bus wiring lines are connected to the via hole.

5. The semiconductor module as claimed in claim 1, wherein each of the semiconductor devices comprises an index.

6. The semiconductor module as claimed in claim 1, wherein each of the signal bus wiring lines is led out from a sending-end semiconductor and terminated with a terminal element.

7. The semiconductor module as claimed in claim 1, wherein the first semiconductor devices and the second semiconductor devices have the same angle of rotation.

8. The semiconductor module as claimed in claim 1, wherein the first semiconductor devices and the second semiconductor devices have different angles of rotation from each other.

9. The semiconductor module as claimed in claim 8, wherein each of the semiconductor devices has a rectangular shape,
the angle of rotation is equal to 90 degrees, and
the first semiconductor devices are mutually connected in a horizontal direction by the signal bus wiring lines.

10. The semiconductor module as claimed in claim 8, wherein each of the first semiconductor devices has the same angle of rotation.

11. The semiconductor module as claimed in claim 3, wherein the number of the second semiconductor devices is three or more, and
the three or more second semiconductor devices include at least one semiconductor device having a different angle of rotation

12. The semiconductor module as claimed in claim 1, wherein the first semiconductor devices have different angles of rotation from each other.

13. A semiconductor module comprising
a substrate;
a pair of first semiconductor devices arranged on said substrate;
a second semiconductor device arranged between said pair of first semiconductor devices on said substrate; and
a signal bus wiring line connecting said pair of first semiconductor devices without connecting said second semiconductor.

14. A semiconductor module comprising:
a substrate;
a pair of first semiconductor devices arranged on said substrate;
a pair of second semiconductor devices arranged on said substrate;
a first signal bus wiring line connecting said pair of first semiconductor devices without connecting said second semiconductor; and
a second signal bus wiring line connecting said pair of second semiconductor devices without connecting said first semiconductor.
